(19) United States
(12) Patent Application Publication
(10) Pub. No.: US 2026/0201196 A1
(43) Pub. Date: Jul. 16, 2026

(54) HEAT RESISTANT COATING AND COATED ARTICLES OR STRUCTURES

(71) Applicant: PHAZEBREAK COATINGS, INC., Olathe, KS (US)

(72) Inventors: Donald P. Browning, Olathe, KS (US); Maria Elisa Cantu-Browning, Olathe, KS (US)

(21) Appl. No.: 19/448,791

(22) Filed: Jan. 14, 2026

Related U.S. Application Data
(60) Provisional application No. 63/745,023, filed on Jan. 14, 2025.

(51) Int. Cl. C09D 125/14; C09D 7/40; C09D 7/61; H02S 40/42; H05K 7/20

(52) U.S. Cl. CPC C09D 125/14; C09D 7/61; C09D 7/69; H02S 40/42; H05K 7/20709

(57) ABSTRACT

A coating composition includes particular amounts of a film-forming polymer, a plurality of ceramic particles, an inorganic pigment, and a carrier. The coating composition can be particularly useful for providing coated articles or structures. The coated articles or structures can exhibit improved heat reduction capabilities.

### CROSS REFERENCE TO RELATED APPLICATIONS

This application claims priority to U.S. Provisional Application Ser. No. 63/745,023, filed on Jan. 14, 2025, and all the benefits accruing therefrom, the content of which is incorporated herein by reference in its entirety.

### BACKGROUND

This disclosure relates to coatings and coated articles or structures. Articles such as photovoltaic devices, including solar panels and systems, and structures such as data centers, are often used under various conditions including heat. To protect the articles and structures, a coating can be applied.

There remains a need in the art for a coating for devices and structures with improved heat reduction capabilities.

### SUMMARY

A coating composition includes 1 to 20 weight percent of a film-forming polymer; 20 to 80 weight percent of ceramic particles; 1 to 30 weight percent of an inorganic pigment; and 10 to 50 weight percent of a carrier; wherein weight percent is based on a total weight of the coating composition.

A coated article or structure includes a substrate or structure; and a coating disposed on a surface of the substrate or structure, wherein the coating is derived from the coating composition of the present disclosure.

A coated data center includes a data center having a roof and side walls, and a coating disposed on the roof, at least one of the side walls, or a combination thereof, wherein the coating is derived from the coating composition as described herein.

A coated photovoltaic device includes a photovoltaic device having a first surface for receiving incoming light and an opposing second surface, and a coating disposed on at least the first surface, the second surface, or both the first and second surfaces of the photovoltaic device, wherein the coating is derived from the coating composition as described herein.

A power generation system comprises the coated photovoltaic device.

A method for forming a coated article or structure comprises applying the coating composition as described herein on a surface of the article or structure; and allowing the coating composition to dry to form a coating.

A method of protecting an article or structure subject to heat includes applying the coating composition as described herein on a surface of the article or structure, and forming a coated article or structure by drying the coating composition.

A method of protecting a photovoltaic device comprises applying a coating composition on a first surface, an opposing second surface, or both the first surface and the second surface of the photovoltaic device; and forming a coating on the first surface, the second surface, or both the first surface and the second surface of the photovoltaic device, wherein the coating composition comprises 1 to 20 weight percent of a film-forming polymer; 20 to 80 weight percent of ceramic particles; 1 to 30 weight percent of an inorganic pigment; and 10 to 50 weight percent of a solvent; wherein weight percent is based on a total weight of the coating composition.

The above described and other features are exemplified by the following figures and detailed description.

### BRIEF DESCRIPTION OF THE DRAWINGS

The following figures are exemplary embodiments wherein the like elements are numbered alike.

FIG. 1 is a schematic cross-sectional view of a coated article or structure; and

FIG. 2 is a schematic cross-sectional view of a coated photovoltaic device according to one or more embodiments.

### DETAILED DESCRIPTION

The present disclosure relates to coatings and coated articles such as coated photovoltaic devices and coated structures such as coated buildings and data centers. In particular, the coatings described herein can enhance the thermal properties of the coated articles and structures. For example, the coatings may reduce the temperature at the interior or exterior of the devices or structures when exposed to heat.

The coatings of the present disclosure can be made from a coating composition comprising a film-forming polymer, a plurality of ceramic particles, an inorganic pigment, and a carrier such as a solvent.

The film-forming polymer of the coating composition can comprise, for example, a pure acrylic, a rubber, a styrene butadiene rubber, a styrene acrylic, a vinyl acrylic, or an acrylated ethylene vinyl acetate copolymer. Preferably, the film-forming polymer is derived from at least one acrylic monomer selected from acrylic acid, acrylic acid esters, methacrylic acid, and methacrylic acid esters. Exemplary monomers employed in emulsion polymerization can include methyl acrylate, methyl methacrylate, ethyl acrylate, ethyl methacrylate, butyl acrylate, butyl methacrylate, propyl acrylate, propyl methylacrylate, 2-ethyl hexyl acrylate and methacrylate, cyclohexyl acrylate and methacrylate, decyl acrylate and methacrylate, isodecylacrylate and methacrylate, benzyl acrylate and methacrylate, other acrylates, methacrylates and their blends, acrylic acid, methacrylic acid, styrene, vinyl toluene, vinyl acetate, vinyl esters of higher carboxylic acids than acetic acid, for example, vinyl versatate, acrylonitrile, acrylamide, butadiene, ethylene, vinyl chloride and the like, and mixtures thereof.

In some aspects, the film-forming polymer can an acrylic polymer or copolymer, rubber-based polymers and copolymers such as styrene-butadiene rubber, copolymers of styrene and acrylic, copolymers of vinyl acetate and ethylene, copolymers of vinyl chloride and ethylene, copolymers of vinyl acetate and VeoVa (vinyl ester of versatic acid), copolymers of vinyl laurate and ethylene, terpolymers of vinyl acetate, ethylene and methylmethacrylate, terpolymers of vinyl acetate, ethylene and vinyl laurate, terpolymers of vinyl acetate, ethylene and VeoVa (vinyl ester of versatic acid), and any combination thereof.

The film-forming polymer can be water-soluble, for example, a latex polymer. The polymer can be used in either liquid form or as a re-dispersible polymer. During the drying of the coating composition, the film-forming polymer may be crosslinked.

Preferably, the film-forming polymer comprises acrylic polymers and copolymers, rubber-based polymers and copolymers such as styrene-butadiene rubber, copolymers of styrene and acrylic, copolymers of vinyl acetate and ethylene, and copolymers of vinyl chloride and ethylene.

The pure acrylics can include acrylic acid, methacrylic acid, an acrylate ester, and/or a methacrylate ester as the main monomers. The styrene acrylics can comprise styrene and acrylic acid, methacrylic acid, an acrylate ester, and/or a methacrylate ester as the main monomers. The vinyl acrylics can comprise vinyl acetate and acrylic acid, methacrylic acid, an acrylate ester, and/or a methacrylate ester as the main monomers. The acrylated ethylene vinyl acetate copolymers can comprise ethylene, vinyl acetate and acrylic acid, methacrylic acid, an acrylate ester, and/or a methacrylate ester as the main monomers. The monomers can also include other main monomers such as acrylamide and acrylonitrile, and one or more functional monomers such as itaconic acid and ureido methacrylate, as would be readily understood by those skilled in the art.

A film-forming polymer can comprise one or more esters of acrylic or methacrylic acid, typically a mixture, e.g., 1:1 by weight, of a high glass transition temperature (T_{g}) monomer (e.g., methyl methacrylate) and a low T_{g} monomer (e.g., butyl acrylate), with small proportions, e.g., 0.5 to 2 wt %, of acrylic or methacrylic acid. The vinyl-acrylic polymers for example include vinyl acetate and butyl acrylate and/or 2-ethyl hexyl acrylate and/or vinyl versatate. In a typical vinyl-acrylic polymer, at least 50% of the polymer formed comprises vinyl acetate, with the remainder being selected from the esters of acrylic or methacrylic acid. The styrene/acrylic polymers are typically similar to the acrylic polymers, with styrene substituted for all or a portion of the methacrylate monomer.

The film-forming polymer can have any suitable molecular weight provided that the film-forming properties are not adversely affected. For example, the film-forming polymer can have a weight average molecular weight of greater than or equal to 10,000 grams per mole (g/mol), for example, 30,000 to 5,000,000 g/mol, or 100,000 to 2,500,000 g/mol, or 150,000 to 1,000,000 g/mol.

The film-forming polymer can be present in the coating composition in an amount of 1 to 20 weight percent, based on a total weight of the coating composition. Within this range, the film-forming polymer can be present in an amount of at least 2 weight percent, or at least 5 weight percent or at least 7 weight percent, or at least 10 weight percent, or at least 12 weight percent, or at least 15 weight percent, each based on the total weight of the coating composition. Also within this range, the film-forming polymer can be present in the coating composition in an amount of at most 18 weight percent, or at most 15 weight percent, or at most 13 weight percent, or at most 10 weight percent. In an aspect, the film-forming polymer may be present in an amount of, for example, 5 to 15 weight percent, each based on the total weight of the coating composition.

In addition to the film-forming polymer, the coating composition comprises a plurality of ceramic particles. The ceramic particles generally have an average particle size of 1000 micrometers or less, for example 500 micrometers or less, or 100 micrometers or less, or 50 micrometers of less. In an aspect, the ceramic particles can have a D90 particle size of 80 micrometers or less, 70 micrometers or less, 60 micrometers or less, 50 micrometers or less, or 40 micrometers or less, preferably 10 to 50 micrometers, 15 to 50 micrometers, 10 to 30 micrometers, or 15 to 25 micrometers. The term “D90 particle size” as used herein refers to the point on the particle size distribution curve at which 90% of the particles have a diameter that is equal to or less than the D90. In other words, only 10% of the particles will have a particle size that is larger than the D90. Particle size can be determined by, for example, light scattering methods or microscopy as is generally known in the art.

As used herein, ceramics can refer to both crystalline ceramics and amorphous (non-crystalline) ceramics. The ceramic particles can be inorganic metal-containing (including metalloid-containing) oxides (e.g., alumina, silica, iron oxide, ceria, zirconia, etc.) or non-oxides (e.g., carbide, boride, nitride, etc.) particles. In an aspect, the ceramic particles can comprise alkali aluminosilicate particles including sodium aluminosilicate particles and sodium, potassium, aluminosilicate particles, glass spheres, or a combination thereof.

The aluminosilicate particles can take on a variety of forms. For example, in some aspects of the coatings, the aluminosilicate particles can be expanded perlite microparticles having multichambered internal porosities; in other aspects of the coatings,
the aluminosilicate particles can be hollow aluminosilicate spheres, which are also referred to as micro-balloons; and in other aspects of the coatings, the aluminosilicate particles can comprise fly ash particles.

Suitable ceramic particles can include those sold under the 3M™ Ceramic Microspheres (e.g., W-210, W-410, or W-610), ceramic microspheres by Tipton Corporation, and inert ceramic materials sold as Ceramic Balls (e.g., BSS18) or High Alumina Balls (e.g., BSS99). In an aspect, the ceramic particles can comprise cenospheres, which are mainly formed of silica and alumina and are understood as hollow spheres produced as a by-product of coal combustion. Exemplary cenospheres include those available from CenoStar Corporation, or under the trade name Fillite™ from Omya UK Ltd. Optionally, the ceramic particles can be metal-coated using metals such as nickel, iron, copper, tin, silver, and gold. In some aspects, no metal coating is present on the ceramic particles.

The ceramic particles can be present in the coating composition in an amount of 20 to 80 weight percent, based on the total weight of the coating composition. Within this range, the ceramic particles can be present in an amount of at least 25 weight percent, or at least 30 weight percent, or at least 35 weight percent, or at least 40 weight percent, or at least 45 weight percent, each based on the total weight of the coating composition. Also within this range, the ceramic particles can be present in an amount of at most 75 weight percent, or at most 70 weight percent, or at least 65 weight percent, or at most 60 weight percent, or at most 55 weight percent, or at most 50 weight percent. For example, the ceramic particles may be present in an amount of 30 to 60 weight percent, or 40 to 60 weight percent, each based on the total weight of the coating composition.

In addition to the film-forming polymer and the ceramic particles, the coating composition further comprises an inorganic pigment. The inorganic pigment can be a metal salt, for example a calcium sulfate, a barium sulfate, a magnesium carbonate, a calcium carbonate, an aluminate, a silicate, an aluminum oxide, a titanium dioxide, a zinc oxide, a zinc sulfide, a silicon dioxide or an argillaceous earth. Combinations of inorganic pigments can also be used. The inorganic pigment can preferably be a white inorganic pigment. A white pigment is understood to refer to a pigment which has no significant absorption of light at a wavelength of from 400 to 800 nanometers (nm). Preferred inorganic pigments can include calcium sulfate, a calcium aluminate sulfate, a barium sulfate, a magnesium carbonate, a calcium carbonate, a silica, an alumina, an aluminum hydrate, a silicate, a titanium dioxide, a zinc oxide, a kaolin, a talc, or a silicon dioxide. In a specific aspect, the inorganic pigment can comprise titanium dioxide.

The inorganic pigment can be present in the coating composition in an amount of 1 to 30 weight percent, based on the total weight of the composition. Within this range, the inorganic pigment can be present in an amount of at least 2 weight percent, or at least 5 weight percent, or at least 8 weight percent, or at least 10 weight percent, or at least 12 weight percent, each based on the total weight of the coating composition. Also within this range, the inorganic pigment can be present in amount of at most 25 weight percent, or at most 20 weight percent, or at most 18 weight percent, or at most 16 weight percent. For example, in an aspect, the inorganic pigment can be present in an amount of 5 to 25 weight percent, each based on the total weight of the coating composition.

The coating composition further comprises a carrier capable of dissolving or dispersing the components of the composition. In an aspect, the coating composition is an aqueous coating composition, wherein the composition includes water as the main carrier. The solids content of the coating composition can be 40 to 90 weight percent, or 50 to 85 weight percent, or 60 to 80 weight percent. Volatile organic compounds (VOCs) refer to chemicals that evaporate into the air as the coating composition dries. Advantageously, the coating composition has minimal or non VOCs. For example, the coating composition can contain zero to less than 5 grams of VOCs per liter of the coating composition.

In an aspect, the carrier (e.g., solvent) can be present in an amount of 10 to 50 weight percent, based on the total weight of the coating composition. Within this range, the carrier (e.g., solvent) can be present in an amount of 10 to 45 weight percent, or 10 to 40 weight percent, or 10 to 35 weight percent, or 10 to 30 weight percent, each based on the total weight of the coating composition.

The coating composition can optionally further comprise an additive composition. When present, the additive composition can be present in an amount of 0.001 to 10 weight percent, based on the total weight of the coating composition. For example, the coating composition can include one or more of a thickener, a defoamer, a dispersant, a wetting agent, a preservative, or a fungicide.

Suitable thickeners can include, for example, polysaccharide polymers such as cellulose, alkyl celluloses, alkoxy celluloses, hydroxy alkyl celluloses, alkyl hydroxy alkyl celluloses, carboxy alkyl celluloses, carboxy alkyl hydroxy alkyl celluloses, naturally occurring polysaccharide polymers such as xanthan gum, guar gum, locust bean gum, tragacanth gum, or derivatives thereof, polycarboxylate polymers, polyacrylamides, clays, and mixtures thereof. Examples of the cellulose derivatives include methyl cellulose ethyl cellulose, hydroxymethyl cellulose hydroxy ethyl cellulose, hydroxy propyl cellulose, carboxy methyl cellulose, carboxy methyl hydroxyethyl cellulose, hydroxypropyl cellulose, hydroxy propyl methyl cellulose, ethylhydroxymethyl cellulose and ethyl hydroxy ethyl cellulose. Clay thickeners comprise, for example, colloid-forming clays, for example, such as smectite and/or attapulgite types. The clay materials can be described as expandable layered clays, i.e., aluminosilicates and magnesium silicates. The term “expandable” as used to describe the instant clays relates to the ability of the layered clay structure to be swollen, or expanded, on contact with water. The expandable clays used herein are those materials classified geologically as smectites (or montmorillonite) and attapulgites (or polygorskites). In a specific aspect, a combination of a clay and cellulose thickener may be used.

The thickener constituent may be present in amount which is found to be effective in increasing the viscosity of the compositions to a desired viscosity. The viscosity of the compositions may be measured according to known techniques, for example using a Brookfield Type III viscometer, #2 spindle, 20 rpm at room temperature (20° C.). While it is clearly understood that the amount of a particular thickener constituent needed to produce a desired viscosity may vary depending upon the nature of the particular thickener constituent and the other constituents present in the composition, when present, in some aspects the thickener can be included in the coating composition in an amount of 0.01 to 5 weight percent, based on the total weight of the coating composition.

There is significant overlap among defoamers and wetting agents, which collectively can be referred to as surface active agents. Surface active agents can be nonionic, anionic, or cationic. In an aspect, a nonionic surface active agent may be preferred.

Nonionic surface active agents can include a water-solubilizing polyalkoxylene or a mono- or di-alkanolamide group in chemical combination with an organic hydrophobic group derived, for example, from alkylphenols in which the alkyl group contains from 6 to 12 carbon atoms, dialkylphenols in which each alkyl group contains from 6 to 12 carbon atoms, primary, secondary or tertiary aliphatic alcohols (or alkyl-capped derivatives thereof), preferably having from 8 to 20 carbon atoms, monocarboxylic acids having from 10 to 24 carbon atoms in the alkyl group and polyoxypropylenes. Also common are fatty acid mono- and dialkanolamides in which the alkyl group of the fatty acid radical contains from 10 to 20 carbon atoms and the alkyloyl group having from 1 to 3 carbon atoms. In any of the mono- and di-alkanolamide derivatives, optionally, there may be a polyoxyalkylene moiety joining the latter groups and the hydrophobic part of the molecule. In all polyalkoxylene containing surfactants, the polyalkoxylene moiety preferably consists of from 2 to 20 groups of ethylene oxide or of ethylene oxide and propylene oxide groups.

Other suitable surface active agents include alkanol amides of fatty acids, having from 16 to 22 carbon atoms, alternatively from 16 to 18 carbon atoms, suitable examples of which include stearic monoethanolamide, stearic diethanolamide, stearic monoisopropanolamide and stearic monoethanolamide stearate. Other long chain acyl derivatives include long chain esters of long chain fatty acids (e.g., stearyl stearate, cetyl palmitate, etc.); long chain esters of long chain alkanol amides (e.g., stearamide diethanolamide distearate, stearamide monoethanolamide stearate); and glyceryl esters as previously described. Long chain acyl derivatives, ethylene glycol esters of long chain carboxylic acids, long chain amine oxides, and alkanol amides of long chain carboxylic acids can also be used as surface active agents.

In an aspect, the composition can comprise a polymeric anionic dispersant, which can be a polymer functionalized with more than one anionic group, promotes the formation of a stable aqueous dispersion of the pigment particles. As distinct from surfactants, polymeric anionic dispersants comprise a plurality of anionic groups, preferably at least 5 anionic groups per molecule. Mechanistically, dispersants interact with the inorganic pigment or the ceramic particles at the water-particle interface; in contrast, surfactants interact with the air-water phase. Consequently, surfactants lower the air-water surface tension whereas dispersants do not significantly lower surface tension.

Examples of suitable dispersants include salts of a homopolymer or a copolymer a carboxylic acid monomer; a copolymer of maleic anhydride and diisobutylene; a copolymer of styrene and maleic anhydride; carboxylmethyl cellulose; and a homopolymer or copolymer with a plurality of sulfate, sulfonate, phosphate, or phosphonate groups, or combinations thereof, attached to the polymer or copolymer backbone.

Suitable carboxylic acid monomers include acrylic acid, methacrylic acid, or itaconic acid, or a combination thereof as well as anhydrides of carboxylic acid monomers, such as methacrylic anhydride and maleic anhydride. Acrylic acid is a preferred carboxylic acid monomer. Examples of monomers suitable to form carboxylic acid functionalized copolymers include nonionic acrylate or methacrylates such as ethyl acrylate, butyl acrylate, methyl methacrylate, butyl methacrylate, 2-ethylhexyl acrylate, and benzyl methacrylate, and combinations thereof. Suitable counterions for the dispersants include Li⁺, Na⁺, K⁺, and NH₄⁺ counterions, as well as alkanolamines such as 2-amino-2-methyl-1-propanol.

The weight average molecular weight (M_{w}) of the dispersant can be, for example, 2,000 to 300,000 g/mol, or 2,000 to 200,000 g/mol. Molecular weight can be determined using known techniques, such as size exclusion chromatography using polyacrylic acid standards.

Commercial examples of salts of polyacrylic acids and copolymers thereof include TAMOL 945, TAMOL 1124, TAMOL 681, TAMOL 2002 Dispersant (supplied as the polyacid and subsequently neutralized), and TAMOL 2011 Dispersants, commercially available from The Dow Chemical Company. Commercial examples of salts of copolymers of maleic anhydride and diisobutylene include TAMOL 731A and TAMOL 165 Dispersants; WALOCEL™ C USP/EP and WALOCEL CRT 40000 Carboxymethyl Cellulose Sodium Salts are commercial examples of salts of carboxylmethyl cellulose, commercially available from The Dow Chemical Company. SMA 1440H Dispersant is a commercial example of a salt of a copolymer of styrene and maleic anhydride; and ACUMER™ 2100 and 3100 Dispersants are commercial examples of polymers containing sulfonate groups, commercially available from The Dow Chemical Company.

The preservative can include a biocide (e.g., fungicides, algaecides, and the like) selected from among formaldehyde and formaldehyde-releasing compounds, isothiazolinones such as N-octylisothiazolone, 4,5-dichloroisothiazolone, n-butylbenzisothiazolone, benzimidazole derivatives such as carbendazim, thiabendazole and their salts, triazole and imidazole derivatives such as tebuconazole and propiconazole, iodine compounds such as iodopropinyl butylcarbamate, diidomethyltolyl sulphone, pyridine derivatives such as zinc pyrithione and 2,3,5,6-tetrachloro-4-methylsulphonylpyridine, triazine derivatives such as terbutryn, prometryn and Irgarol 1051, urea derivatives such as diuron, isoproturon, dithiocarbamates such as ziram, thiram, hydroxylamine derivatives such as the potassium and aluminium salts of N-cyclohexyl-N-nitrosohydroxylamine, and 2-(thiocyanatomethylthio)benzothiazole (TCMTB), benzothiophene-2-cyclohexylcarboxamide S,S-dioxide and tetrachloroisophthalonitrile. Combinations of the abovementioned preservatives are also contemplated.

The coating composition can be prepared by combining the components of the coating composition. Preferably, the coating composition as described herein is a one-package coating composition.

The coating composition can be applied to various substrates or structures such as metallic substrates or structures, polymeric substrates or structures, composite substrates or structures, glass substrates or structures, and the like by any of the suitable application methods, such as spraying, knife coating, spreading, pouring, dipping, impregnating, trickling or rolling, for example. In the course of such application, the substrate or structure to be coated may itself be at rest, with the application equipment or unit being moved. Alternatively the substrate to be coated may be moved, with the application unit being at rest relative to the substrate or being moved appropriately.

Optionally, prior to the application of the coating composition to the substrate or structure, the substrate or structure may first be coated with a primer or a primer system which may comprise several layers. For example, the primer system may include an anti-erosion primer layer optionally followed by a layer of an adhesion-promoting primer. In some aspects, no primer layers are present between the coating composition of the substrate or structure.

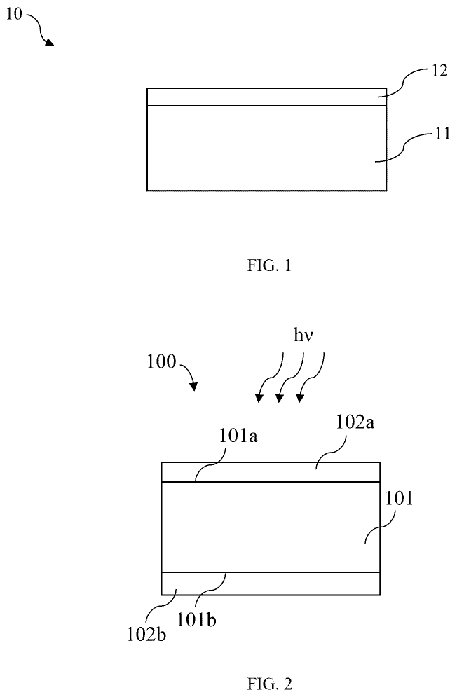

After drying, a coating is formed from the coating composition. Referring to FIG. 1, a coated article or structure 10 can comprise a substrate or structure 11; and a coating 12 disposed on a surface of the substrate or structure, wherein the coating is derived from the coating composition as described herein. As used herein, the coating can comprise the film-forming polymer or a crosslinked product thereof, the plurality of ceramic particles, and the inorganic pigment. The dried coating can comprise, for example, 5 to 30 weight percent, or 10 to 20 weight percent of the film-forming polymer, 40 to 90 weight percent, or 50 to 80 weight percent of the plurality of ceramic particles, 5 to 30 weight percent, or 10 to 25 weight percent of the inorganic pigment, and 0 to 10 weight percent of an additive composition, each based on the dry weight of the coating.

The coating can have a thickness of 5 micrometers to 5 millimeters, 10 micrometers to 2 millimeters, or 50 micrometers to 1 millimeter. The coating can comprise the plurality of ceramic particles and the inorganic pigment dispersed in a matrix comprising the film-forming polymer.

The coating can be particularly useful for providing improved thermal management to articles or structures that are subject to heat. Accordingly, a method of protecting an article or structure subject to heat comprises applying the coating composition as described herein on a surface of the article or structure; and forming a coated article or structure by drying the coating composition. Advantageously, the coated article or structure can exhibit a reduced temperature when exposed to heat compared to an otherwise identical article or structure that does not have the coating. The coated article may be a coated photovoltaic device, and a coated structure may be a coated building, a coated housing for a battery or electronic devices, or a coated data center.

In an aspect, a coated data center can comprise a data center having a roof and side walls; and a coating disposed on the roof, at least one of the side walls, or a combination thereof, wherein the coating is derived from the coating composition as described herein.

A coated photovoltaic device represents another aspect of the present disclosure.

A coated photovoltaic device includes a photovoltaic device having a first surface for receiving an incoming light, and an opposing second surface; and a coating disposed on the first surface, the second surface, or both the first and second surfaces of the photovoltaic device, wherein the coating is derived from the coating composition described herein. As shown in FIG. 2, a coated photovoltaic device 100 may comprise a photovoltaic device 101 with a first surface 101a and a second surface 101b. A coating may be disposed on the first surface 101a (coating 102a), the second surface 101b (coating 102b), or both the first surface 101a and the second surface 101b. The first surface 101a is oriented at the top of the photovoltaic device facing the incoming light (hv). Preferably, the coating is provided on the second surface 101b and the coating 102b is derived from the coating composition described herein.

The first and second surfaces can be provided by a glass layer or a polymer layer. In an aspect, the first surface is a top surface of a glass layer and the second surface is a bottom surface of a polymer layer or a second glass layer. Preferably, the coating composition is applied to the second surface of the photovoltaic device. Advantageously, the coating can provide improved thermal management for the coated photovoltaic device.

The photovoltaic device that can be coated with the coating composition disclosed herein is not particularly limited. As used herein, a photovoltaic device includes a photovoltaic cell, module, panel, array, and system. In an aspect, the photovoltaic device includes a photovoltaic cell layer including at least one photovoltaic cell between an upper layer (e.g., a glass layer or a polymer layer) and a lower layer (e.g., a polymer backsheet or a glass layer). The photovoltaic cell layer can include a plurality of photovoltaic cells, metallic fingers, and busbars such as flat ribbon busbars and/or thin wire (MBB) busbars. The upper layer, the photovoltaic cell layer, and the lower layer can be supported within a frame.

The photovoltaic device can also include one or more encapsulation layers such as ethylene vinyl acetate films between the upper layer and the solar photovoltaic cell layer, between the lower layer and the photovoltaic cell layer, or a combination thereof. The photovoltaic device can also include an anti-reflective layer disposed on the photovoltaic cell layer.

The photovoltaic device also includes an electrical component such as a junction box including connectors and/or bypass diodes. Other suitable electrical components can be present if needed.

The coating can be formed by removing the carrier (e.g., solvent) from the applied coating composition. For example, removing the solvent from the applied coating composition can be conducted at a temperature of 30 to 200° C., more preferably 30 to 150° C., and in particular 30 to 100° C. for a time of 1 minute (min) up to 70 hours (h), more preferably 1 h up to 60 h, and in particular 5 h to 50 h.

This disclosure is further illustrated by the following examples, which are non-limiting.

### EXAMPLES

### Example 1

Effectiveness of the heat reduction coatings according to the present disclosure were tested by comparing a control box coated with white paint (Comparative Example 1) to a box coated with a coating composition including a styrene-acrylate copolymer; an alkali aluminosilicate ceramic, titanium dioxide, water, a thickener, a defoamer, a dispersant, a surface-active agent, a preservative, and a fungicide (Example 1). At selected time intervals, the temperature of the outer surface and the inside of the box was taken. Results are shown in Table 1.

TABLE 1

| | | Comparative | | |
|---|---|---|---|---|
| | Inside/ | Example 1 | Example 1 | Difference |
| Time | Outside | (° C.) | (° C.) | (° C.) |
| 1:30 | Inside | 90 | 90 | 0 |
| 1:30 | Outside | 100 | 100 | 0 |
| 1:35 | Inside | 93 | 94 | 1 |
| 1:35 | Outside | 104 | 101 | −3 |
| 1:40 | Inside | 98 | 93 | −5 |
| 1:40 | Outside | 103 | 99 | −4 |
| 1:45 | Inside | 100 | 100 | 0 |
| 1:45 | Outside | 103 | 100 | −3 |
| 2:00 | Inside | 98 | 99 | 1 |
| 2:00 | Outside | 101 | 98 | −3 |
| 2:15 | Inside | 98 | 99 | 1 |
| 2:15 | Outside | 105 | 101 | −4 |
| 2:30 | Inside | 95 | 94 | −1 |
| 2:30 | Outside | 96 | 93 | −3 |
| 3:00 | Inside | 102 | 100 | −2 |
| 3:00 | Outside | 108 | 104 | −4 |
| 3:15 | Inside | 94 | 93 | −1 |
| 3:15 | Outside | 98 | 96 | −2 |

As shown in Table 1, overall, the box coated with the coating composition of Example 1 exhibited reduced outside temperatures and/or reduced insider temperature as compared to the Comparative Example.

### Example 2

Effectiveness of the heat reduction coatings according to the present disclosure were tested by comparing a control box coated with black paint (Comparative Example 2) to a box coated with a coating composition including a styrene-acrylate copolymer; an alkali aluminosilicate ceramic, titanium dioxide, water, a thickener, a defoamer, a dispersant, a surface-active agent, a preservative, and a fungicide (Example 2). At selected time intervals, the temperature of the outer surface and the inside of the box was taken. Results are shown in Table 2.

TABLE 2

| | | Comparative | | |
|---|---|---|---|---|
| | Inside/ | Example 2 | Example 2 | Difference |
| Time | Outside | (° C.) | (° C.) | (° C.) |
| 1:05 | Inside | 80 | 80 | 0 |
| 1:05 | Outside | 83 | 83 | 0 |
| 1:15 | Inside | 90 | 80 | −10 |
| 1:15 | Outside | 136 | 87 | −49 |
| 1:30 | Inside | 109 | 90 | −19 |
| 1:30 | Outside | 138 | 87 | −51 |
| 1:45 | Inside | 100 | 83 | −17 |
| 1:45 | Outside | 129 | 80 | −49 |
| 2:15 | Inside | 110 | 80 | −30 |
| 2:15 | Outside | 130 | 82 | −48 |

As shown in Table 2, the box coated with the composition according to the present disclosure (Example 2) showed a significant heat reduction both inside and outside the box compared to the black box of Comparative Example 2. The average temperature difference inside the box was −19° C., while the average temperature difference outside the box was −49° C. A significant improvement in thermal management coatings is therefore provided by the present disclosure.

This disclosure further encompasses the following aspects.

Aspect 1: A coating composition comprising: 1 to 20 weight percent of a film-forming polymer; 20 to 80 weight percent of a plurality of ceramic particles; 1 to 30 weight percent of an inorganic pigment; and 10 to 50 weight percent of a carrier (e.g., solvent); wherein weight percent is based on a total weight of the coating composition.

Aspect 2: The coating composition of aspect 1, wherein the film-forming polymer comprises an acrylic polymer, a styrene acrylic copolymer, or a combination thereof.

Aspect 3: The coating composition of aspect 1 or 2, wherein the film-forming polymer comprises a styrene acrylic copolymer.

Aspect 4: The coating composition of any of aspects 1 to 3, wherein the plurality of ceramic particles comprises alkali aluminosilicate ceramic particles, glass spheres, or a combination thereof.

Aspect 5: The coating composition of any of aspects 1 to 4, wherein the ceramic particles of the plurality of ceramic particles have a D90 particle size of less than 80 micrometers, preferably 15 to 50 micrometers.

Aspect 6: The coating composition of any of aspects 1 to 5, wherein the inorganic pigment comprises calcium sulfate, calcium aluminate sulfate, barium sulfate, magnesium carbonate, calcium carbonate, silica, alumina, aluminum hydrate, silicate, titanium dioxide, zinc oxide, kaolin, talc, or silicon dioxide.

Aspect 7: The coating composition of any of aspects 1 to 6, wherein the carrier is an aqueous solvent.

Aspect 8: The coating composition of any of aspects 1 to 7, wherein the carrier is water.

Aspect 9: The coating composition of any of aspects 1 to 8, comprising: 5 to 15 weight percent of the film-forming polymer; 40 to 60 weight percent of the plurality of ceramic particles; 5 to 25 weight percent of the inorganic pigment; and 10 to 30 weight percent of the carrier; wherein weight percent is based on a total weight of the coating composition.

Aspect 10: The coating composition of any of aspects 1 to 9, further comprising 0.001 to 10 weight percent of an additive composition, based on the total weight of the coating composition.

Aspect 11: The coating composition of aspect 10, wherein the additive composition comprises one or more of a thickener, a defoamer, a dispersant, a wetting agent, a preservative, or a fungicide.

Aspect 12: A coated article or structure comprising: a substrate or structure; and a coating disposed on a surface of the substrate or structure, wherein the coating is derived from the coating composition of any of aspects 1 to 11.

Aspect 13: The coated article or structure of aspect 12, wherein the article or the structure exhibits a reduced temperature when exposed to heat compared to an otherwise identical article or structure that lacks the coating.

Aspect 14. A coated data center comprising a data center having a roof and side walls; and a coating disposed on the roof, least one of the side walls, or a combination thereof, wherein the coating is derived from the coating composition of any of aspects 1 to 11.

Aspect 15: A coated photovoltaic device comprising: a photovoltaic device having a first surface for receiving incoming light and an opposing second surface, and a coating disposed on at least the first surface, the second surface, or both the first and second surfaces of the photovoltaic device, wherein the coating is derived from a coating composition of any of aspects 1 to 11.

Aspect 15a: The coated photovoltaic device of aspect 15, wherein the first surface is a top surface of a glass layer, and the second surface is a bottom surface of a polymer sheet or a glass layer.

Aspect 15b: The coated photovoltaic device of any of aspects 15 or 15a, wherein the photovoltaic device is a photovoltaic cell, module, panel, array, or system.

Aspect 16: A power generation system comprising the coated photovoltaic device of any of aspects 15 to 15b.

Aspect 17. A method for forming a coated article, the method comprising: providing an article; applying the coating composition of any of claims 1 to 11 on a surface of the article; and drying the coating composition to form a coating.

Aspect 18. A method of protecting an article or structure subject to heat, the method comprising applying the coating composition of any of claims 1 to 11 on a surface of the article or structure; and forming a coated article or structure by drying the coating composition.

Aspect 19. The method of aspect 18, wherein the coated article or the coated structure exhibits a reduced temperature when exposed to heat compared to an otherwise identical article or structure that does not have the coating.

Aspect 20. The method of any of aspects 18 to 19, wherein the article is a photovoltaic device, and the structure is a data center.

Aspect 21: A method of protecting a photovoltaic device, the method comprising applying a coating composition on a first surface, an opposing second surface, or both the first surface and the second surface of the photovoltaic device; and forming a coating on the first surface, the second surface, or both the first surface and the second surface of the photovoltaic device, wherein the coating composition comprises 1 to 20 weight percent of a film-forming polymer; 20 to 80 weight percent of a plurality of ceramic particles; 1 to 30 weight percent of an inorganic pigment; and 10 to 50 weight percent of a solvent; wherein weight percent is based on a total weight of the coating composition.

The compositions, methods, and articles can alternatively comprise, consist of, or consist essentially of, any appropriate components or steps herein disclosed. The compositions, methods, and articles can additionally, or alternatively, be formulated so as to be devoid, or substantially free, of any steps, components, materials, ingredients, adjuvants, or species that are otherwise not necessary to the achievement of the function or objectives of the compositions, methods, and articles.

The singular forms “a,” “an,” and “the” include plural referents unless the context clearly dictates otherwise. “Or” means “and/or” unless clearly indicated otherwise by context. The terms “substantially” and “generally” are intended to include the degree of error associated with measurement of the particular quantity based upon the equipment available at the time of filing the application. For example, “substantially” and/or “generally” can include a range of ±8% or ±5%, or ±2% of a given value.

“Optional” or “optionally” means that the subsequently described event or circumstance can or cannot occur, and that the description includes instances where the event occurs and instances where it does not. A “combination” is inclusive of blends, mixtures, alloys, reaction products, and the like.

As used herein, the term “hydrocarbyl” and “hydrocarbon” refers broadly to a substituent comprising carbon and hydrogen, optionally with 1 to 3 heteroatoms, for example, oxygen, nitrogen, halogen, silicon, sulfur, or a combination thereof; “alkyl” refers to a straight or branched chain, saturated monovalent hydrocarbon group; “alkylene” refers to a straight or branched chain, saturated, divalent hydrocarbon group; “cycloalkyl” refers to a non-aromatic monovalent monocyclic or multicyclic hydrocarbon group having at least three carbon atoms; “aryl” refers to an aromatic monovalent group containing only carbon in the aromatic ring or rings; “arylene” refers to an aromatic divalent group containing only carbon in the aromatic ring or rings; and “arylalkyl” refers to an alkyl group that has been substituted with an aryl group as defined above, with benzyl being an exemplary arylalkyl group.

Unless otherwise indicated, each of the foregoing groups can be unsubstituted or substituted, provided that the substitution does not significantly adversely affect synthesis, stability, or use of the compound. The term “substituted” as used herein means that at least one hydrogen on the designated atom or group is replaced with another group, provided that the designated atom's normal valence is not exceeded.

Unless otherwise specified herein, any reference to standards, regulations, testing methods and the like refers to the standard, regulation, guidance or method that is in force at the time of filing of the present application.

All cited patents, patent applications, and other references are incorporated herein by reference in their entirety. If a term in the present application contradicts or conflicts with a term in an incorporated reference, the term from the present application takes precedence over the conflicting term from the incorporated reference.

While embodiments have been set forth for the purpose of illustration, the foregoing descriptions should not be deemed a limitation on the scope herein. Accordingly, various modifications, adaptations, and alternatives can occur to one skilled in the art without departing from the spirit and scope herein.

1. A coating composition comprising
1 to 20 weight percent of a film-forming polymer;
20 to 80 weight percent of a plurality of ceramic particles;
1 to 30 weight percent of an inorganic pigment; and
10 to 50 weight percent of a carrier;
wherein weight percent is based on a total weight of the coating composition.

2. The coating composition of claim 1, wherein the film-forming polymer comprises an acrylic polymer, a styrene acrylic copolymer, or a combination thereof.

3. The coating composition of claim 1, wherein the film-forming polymer comprises a styrene acrylic copolymer.

4. The coating composition of claim 1, wherein the plurality of ceramic particles comprises alkali aluminosilicate ceramic particles, glass spheres, or a combination thereof.

5. The coating composition of claim 1, wherein the ceramic particles of the plurality of ceramic particles have a D90 particle size of less than 80 micrometers, preferably 15 to 50 micrometers.

6. The coating composition of claim 1, wherein the inorganic pigment comprises calcium sulfate, calcium aluminate sulfate, barium sulfate, magnesium carbonate, calcium carbonate, silica, alumina, aluminum hydrate, silicate, titanium dioxide, zinc oxide, kaolin, talc, or silicon dioxide.

7. The coating composition of claim 1, wherein the carrier is an aqueous solvent.

8. The coating composition of claim 1, wherein the carrier is water.

9. The coating composition of claim 1, comprising:
5 to 15 weight percent of the film-forming polymer;
40 to 60 weight percent of the plurality of ceramic particles;
5 to 25 weight percent of the inorganic pigment; and
10 to 30 weight percent of the carrier;
wherein weight percent is based on a total weight of the coating composition.

10. The coating composition of claim 1, further comprising 0.001 to 10 weight percent of an additive composition, based on the total weight of the coating composition.

11. The coating composition of claim 10, wherein the additive composition comprises one or more of a thickener, a defoamer, a dispersant, a wetting agent, a preservative, or a fungicide.

12. A coated article or structure comprising:
a substrate or structure; and
a coating disposed on a surface of the substrate or structure,
wherein the coating is derived from the coating composition of claim 1.

13. The coated article or structure of claim 12, wherein the article or the structure exhibits a reduced temperature when exposed to heat compared to an otherwise identical article or structure that lacks the coating.

14. A coated data center comprising:
a data center having a roof and side walls; and
a coating disposed on the roof, least one of the side walls, or a combination thereof,
wherein the coating is derived from the coating composition of claim 1.

15. A coated photovoltaic device comprising:
a photovoltaic device having a first surface for receiving incoming light and an opposing second surface, and
a coating disposed on at least the first surface, the second surface, or both the first and second surfaces of the photovoltaic device,
wherein the coating is derived from a coating composition of claim 1.

16. A power generation system comprising the coated photovoltaic device of claim 15.

17. A method for forming a coated article or a coated structure, the method comprising:
applying the coating composition of claim 1 on a surface of an article or a structure; and
drying the coating composition to form a coating.

18. A method of protecting an article or structure subject to heat, the method comprising:
applying the coating composition of claim 1 on a surface of the article or structure; and
forming a coated article or structure by drying the coating composition.

19. The method of claim 18, wherein the coated article or the coated structure exhibits a reduced temperature when exposed to heat compared to an otherwise identical article or structure that does not have the coating.

20. The method of claim 19, wherein the article is a photovoltaic device, and the structure is a data center.
